(19) United States
(12) Patent Application Publication
(10) Pub. No.: US 2013/0068157 A1
(43) Pub. Date: Mar. 21, 2013

(54) METHOD OF MANUFACTURING SILICON CARBIDE CRYSTAL

(71) Applicants: Makoto Sasaki, Itami-shi (JP); Tsutomu Hori, Itami-shi (JP)

(72) Inventors: Makoto Sasaki, Itami-shi (JP); Tsutomu Hori, Itami-shi (JP)

(73) Assignee: SUMITOMO ELECTRIC INDUSTRIES, LTD., Osaka-shi (JP)

(21) Appl. No.: 13/606,529

(22) Filed: Sep. 7, 2012

Related U.S. Application Data
(60) Provisional application No. 61/537,148, filed on Sep. 21, 2011.

(30) Foreign Application Priority Data
Sep. 21, 2011 (JP) 2011-205456

(51) Int. Cl. C30B 23/00; C23C 14/06

(52) U.S. Cl. 117/84; 427/249.16

(57) ABSTRACT

A method of manufacturing silicon carbide crystal includes the steps of forming silicon carbide crystal on a main surface of a base composed of carbon and removing the base from silicon carbide crystal by oxidizing carbon. According to the manufacturing method, by gasifying the base integrated with the silicon carbide crystal by oxidizing carbon forming the base, the base is removed from the silicon carbide crystal. Therefore, since it is not necessary to apply physical force to the silicon carbide crystal or the base for separating them from each other, occurrence of a defect involved with removal of the base can be suppressed. Therefore, high-quality silicon carbide crystal having fewer defects can be manufactured.

### BACKGROUND OF THE INVENTION

1. Field of the Invention

The present invention relates to a method of manufacturing silicon carbide crystal.

2. Description of the Background Art

Silicon carbide (SiC) crystal has recently increasingly been used for a semiconductor substrate to be used for manufacturing a semiconductor device. SiC is greater in band gap than more generally used silicon (Si). Therefore, since a semiconductor device containing SiC has such advantages as high breakdown voltage, low ON resistance, and less lowering in characteristics in an environment at a high temperature, it has attracted attention.

A sublimation method representing a vapor phase epitaxy method is exemplified as one of such SiC crystal growth methods. For example, Japanese National Patent Publication No. 2008-515749 discloses a method of manufacturing an SiC wafer by forming an SiC boule on a surface of a base made of graphite with a sublimation method, slicing and polishing the wafer, and etching the wafer in molten KOH.

### SUMMARY OF THE INVENTION

Normally, a plurality of substrates are fabricated by slicing SiC crystal in a shape of one ingot with one wire. Therefore, in the case where SiC crystal is sliced while the SiC crystal and the base are integrated, the wire tends to come in contact not only with the SiC crystal but also with the base.

The SiC crystal and the base made of graphite, however, are considerably different from each other in such physical properties as hardness and brittleness. Therefore, in such working processes as slicing and polishing of SiC crystal, contact of a working member such as a wire with both of these different in physical property will impose extra load on the working member. In this case, owing to this load, damage to a working member such as cut of a wire is caused. In addition, damage to the working member may also cause damage to facilities. Moreover, such damage leads to damage to SiC crystal and consequently a defect is caused in SiC crystal. Therefore, in order to improve productivity of a substrate and reduce load on facilities, it is necessary to prepare SiC crystal separated from a base and thereafter subject the SiC crystal to a working process.

The present invention was made in view of the circumstances above, and an object thereof is to provide a method of manufacturing SiC crystal with fewer defects, which is separated from a base.

In order to achieve the object above, the present inventors have conducted studies about separation of a base from SiC crystal by physically applying force to the SiC crystal and the base, as a method of separating the SiC crystal grown on a surface of the base and the base from each other. In this case, however, it was found that cracking or fracture occurred in SiC crystal and consequently a defect was likely to occur in the SiC crystal.

Then, the present inventors have considered a method alternative to the method of separating SiC crystal and a base from each other by physically applying force to the SiC crystal or the base, and paid attention to use of a method of chemically removing the base as such a method. Then, the present inventors have conducted dedicated studies about a method of chemically removing a base from SiC crystal and completed the present invention.

Namely, the present invention is directed to a method of manufacturing SiC crystal, including the steps of forming SiC crystal on a main surface of a base composed of carbon and removing the base from the SiC crystal by oxidizing carbon.

According to the present manufacturing method, by gasifying the base integrated with the SiC crystal by oxidizing carbon forming the base, the base is removed from the SiC crystal. Therefore, since it is not necessary to apply physical force to the SiC crystal or the base for separating them from each other, occurrence of a defect involved with removal of the base can be suppressed. Therefore, high-quality SiC crystal having fewer defects can be manufactured.

The manufacturing method above preferably includes the step of arranging a seed substrate composed of SiC single crystal on the main surface of the base before the forming step.

Thus, SiC crystal having single crystal structure can readily be manufactured on a surface of the seed substrate.

In the manufacturing method above, in the step of arranging a seed substrate, the seed substrate is preferably fixed to the main surface of the base by using a fixing portion composed of carbon.

Thus, the seed substrate and the base can be fixed to each other in a simplified manner. In addition, since the fixing portion is composed of carbon, the fixing portion can be removed by gasifying the same similarly to the base in the step of removing the base.

In the manufacturing method above, in the removing step, the base is preferably heated to a temperature not lower than 500° C. and lower than 1800° C.

Since carbon can thus efficiently be oxidized, a cycle time for manufacturing SiC crystal can be reduced.

In the manufacturing method above, in the removing step, the base is preferably arranged in an atmosphere containing oxygen by not less than 1 volume %.

Since carbon can thus efficiently be oxidized, a cycle time for manufacturing SiC crystal can be reduced.

The manufacturing method above preferably further includes the step of partially removing the base between the step of forming SiC crystal and the step of removing the base.

Thus, since a volume of the base can be made smaller or a surface area of the base can be increased, a time period for oxidizing carbon forming the base can be reduced. Therefore, a cycle time for manufacturing SiC crystal can be reduced.

In the manufacturing method above, preferably, the step of removing the base has the steps of accommodating the base in an internal space of a heating apparatus and heating the accommodated base by heating the internal space of the heating apparatus, and in the accommodating step, the base is arranged in the heating apparatus such that the base and an inner wall of the heating apparatus are not in contact with each other.

Thus, since the entire surface of the base is exposed in the heating apparatus in the step of removing the base, efficiency of contact between the base and oxygen in the heating apparatus is improved. Therefore, a time period for oxidizing the base can be reduced and hence a cycle time for manufacturing SiC crystal can be reduced.

In the manufacturing method above, a ratio H/W between a maximum width W of a surface of the SiC crystal in contact with the base and a maximum length H in a direction of growth of the SiC crystal orthogonal to the surface in contact is preferably not higher than 2/5.

The present inventors have found that, when SiC crystal and a base are physically separated from each other in the case where the SiC crystal has a shape satisfying the ratio above, a probability of occurrence of defects in the SiC crystal tends to increase. Therefore, in the SiC crystal having the shape above, an effect of the present invention can more highly be exhibited.

As described above, according to the method of manufacturing SiC crystal of the present invention, SiC crystal with fewer defects, which is separated from a base, can be manufactured.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic flowchart of a method of manufacturing SiC crystal in a first embodiment.

FIG. 2 is a cross-sectional view schematically showing a first step in the method of manufacturing SiC crystal in the first embodiment.

FIG. 3 is a schematic cross-sectional view showing one example of a sublimation method in the first embodiment.

FIG. 4 is a cross-sectional view schematically showing a second step in the method of manufacturing SiC crystal in the first embodiment.

FIG. 5 is a cross-sectional view schematically showing a third step in the method of manufacturing SiC crystal in the first embodiment.

FIG. 6 is a schematic cross-sectional view showing one example of a method of oxidizing carbon in the first embodiment.

FIG. 7 is a schematic cross-sectional view for illustrating one example of a shape of SiC crystal in the first embodiment.

FIG. 8 is a schematic flowchart of a method of manufacturing SiC crystal in a second embodiment.

FIG. 9 is a cross-sectional view schematically showing a first step in the method of manufacturing SiC crystal in the second embodiment.

FIG. 10 is a cross-sectional view schematically showing a second step in the method of manufacturing SiC crystal in the second embodiment.

FIG. 11 is a cross-sectional view schematically showing a third step in the method of manufacturing SiC crystal in the second embodiment.

FIG. 12 is a cross-sectional view schematically showing a fourth step in the method of manufacturing SiC crystal in the second embodiment.

FIG. 13 is a schematic cross-sectional view for illustrating one example of a shape of SiC crystal in the second embodiment.

FIG. 14 is a cross-sectional view schematically showing another example of the first step in the method of manufacturing SiC crystal in the second embodiment.

### DESCRIPTION OF THE PREFERRED EMBODIMENTS

An embodiment of the present invention will be described hereinafter with reference to the drawings. It is noted that, in the drawings below, the same or corresponding elements have the same reference characters allotted and description thereof will not be repeated. In addition, an individual plane and a collective plane are herein shown in ( )and { }, respectively. Moreover, in teems of crystallography, a negative index should be denoted by a number with a bar “-” thereabove, however, a negative sign herein precedes a number.

### First Embodiment

A method of manufacturing SiC crystal having polycrystalline structure with a sublimation method will be described hereinafter by way of example of the present invention.

(Step of Forming SiC Crystal)

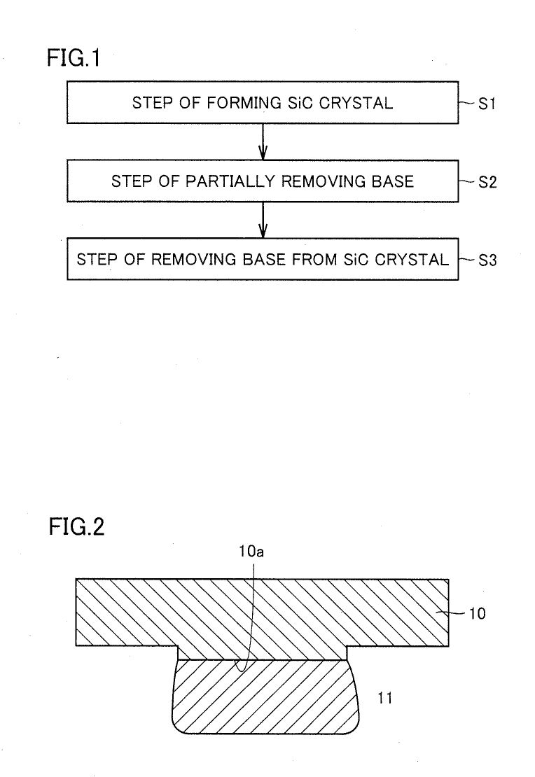

Referring to FIGS. 1 and 2, initially, SiC crystal is formed on a main surface 10a (a lower surface in FIG. 2) of a base 10 (step S1). In the present step, the SiC crystal can be formed as follows.

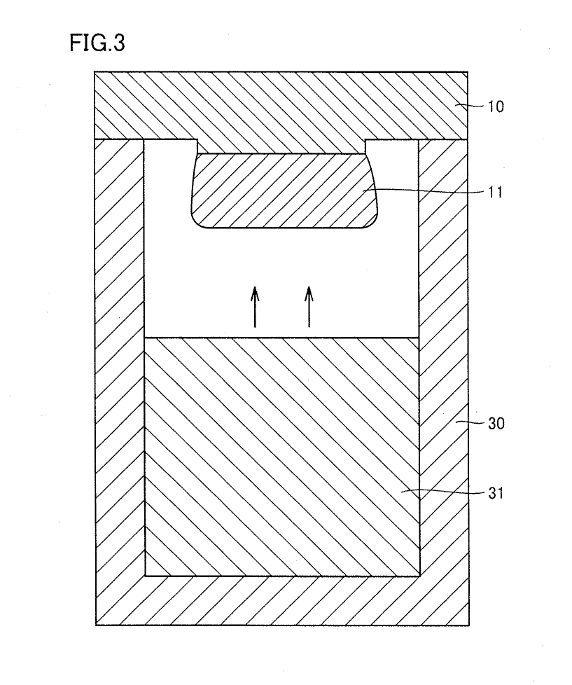

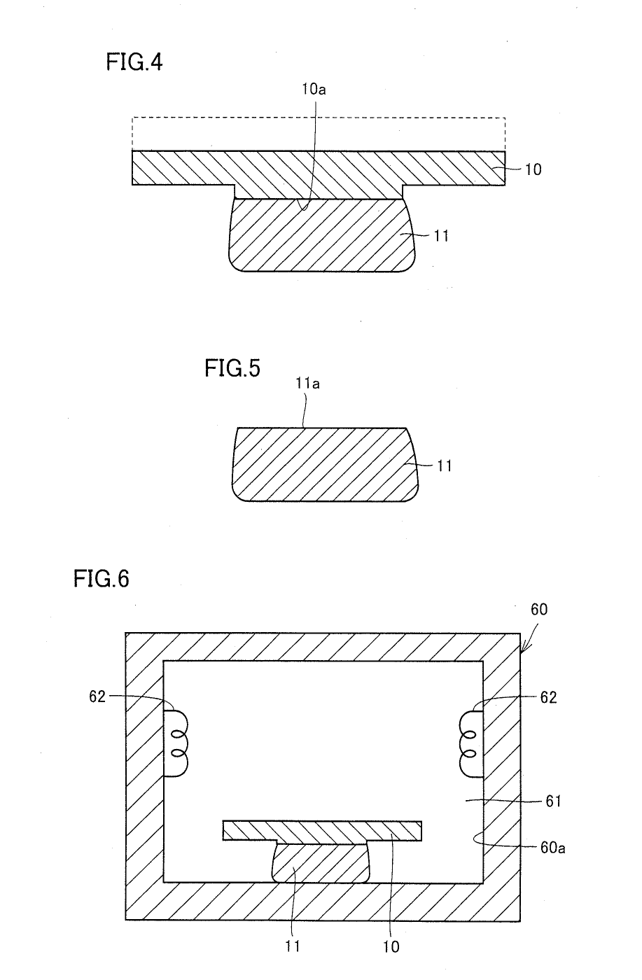

Referring to FIG. 3, initially, a source material 31 is accommodated in a crucible 30, and base 10 is attached such that main surface 10a of base 10 faces the inside of crucible 30. It is noted that base 10 may function as a lid for crucible 30 as shown in FIG. 4.

Base 10 is composed of carbon, and particularly it is preferably composed of graphite. Crucible 30 is preferably a crucible made of graphite in consideration of its durability. Source material 31 is not particularly restricted so long as it generates a source gas such as an SiC₂ gas or an Si₂C gas, and a shape and arrangement thereof are not particularly restricted either so long as the source gas can reach main surface 10a of base 10. For example, in consideration of ease in handling and ease in preparation of a source material, SiC powders are preferably used. SiC powders can be obtained, for example, by crushing SiC polycrystal. Alternatively, in growing SiC crystal doped with such an impurity as nitrogen and phosphorus, an impurity should only be mixed in source material 31.

Then, SiC crystal 11 is grown on main surface 10a of base 10 with a sublimation method. Specifically, a temperature gradient is set in a vertical direction (an up/down direction in FIG. 3) in crucible 30, a region where source material 31 is accommodated is set under a temperature environment in which source material 31 sublimates, and a region where main surface 10a of base 10 is located is set under a temperature environment in which SiC is crystallized. Thus, as shown with an arrow in the figure, source material 31 sublimates and a sublimate is deposited on main surface 10a of base 10. Consequently, SiC crystal 11 can be grown on main surface 10a.

A temperature in crucible 30 in this sublimation method is set, for example, to a temperature not lower than 2100° C. and not higher than 2500° C. A pressure in crucible 30 is set preferably to a pressure not lower than 1.3 kPa and not higher than an atmospheric pressure and more preferably to a pressure not higher than 13 kPa for increasing a growth rate. In addition, in the sublimation method, an inert gas is preferably introduced in crucible 30. For example, by providing an opening in an upper portion of crucible 30, an inert gas can be introduced in crucible 30 through the opening. For example, at least one selected from the group consisting of argon, helium, and nitrogen can be used as the inert gas.

Then, base 10 having SiC crystal 11 fanned on main surface 10a with the sublimation method above is removed from crucible 30. It is noted that, by lowering a temperature in crucible 30, crystal growth with the sublimation method can be stopped and hence SiC crystal 11 having a desired size can be formed. Preferably, a two-dimensional shape of main surface 10a of base 10 encompasses a circle having a diameter of 100 mm. Thus, a substrate having a two-dimensional shape encompassing a circle having a diameter of 100 mm can readily be obtained from SiC crystal 11 grown on this main surface 10a.

(Step of Partially Removing Base)

Referring next to FIGS. 1 and 4, base 10 is partially removed (step S2). In the present step, base 10 can partially be removed as follows.

A portion forming a surface of base 10 other than main surface 10a, i.e., an upper portion of base 10 in FIG. 4, is cut by using a wire saw or the like. It is noted that a region shown with a dotted line in FIG. 4 shows a region of base 10 removed in the present step. Alternatively, base 10 may partially be removed by using other tools such as a dicing blade. An advantage in the present step is as follows.

Namely, base 10 is chemically removed by oxidation in a step (step S3) which will be described later. By performing the present step, however, a volume of base 10 to chemically be removed can be reduced in advance. Therefore, a time period for treatment required for chemically removing base 10 can be reduced.

A part of base 10 to be removed is not limited to the region shown with the dotted line in FIG. 4, and for example, a portion protruding in a lateral direction in FIG. 4 of base 10 may be removed. Alternatively, base 10 may partially be removed such that a surface area of base 10 increases. As the surface area of base 10 increases, efficiency of contact between oxygen and base 10 improves in the step (step S3) which will be described later, and therefore efficiency in oxidation improves and consequently a time period for treatment required for chemically removing base 10 can be reduced.

Here, in an attempt to physically remove a portion of base 10 in contact with SiC crystal 11 by using, for example, a wire saw, for separating the entire base 10 and SiC crystal 11 from each other, the wire saw may cut not only base 10 but also a part of SiC crystal 11. In this case, since the wire saw cuts base 10 and SiC crystal 11 different from each other in such physical properties as hardness and brittleness, great load is imposed on the wire saw. When the wire saw is cut owing to this load, this cutting may result in damage to SiC crystal 11.

Therefore, in the present step, it is necessary to determine a region of base 10 to be removed such that a portion of base 10 in contact with SiC crystal 11 remains. Theoretically, base 10 by a thickness of one atomic layer of carbon from an interface with SiC crystal 11 preferably remains, and in addition, from a point of view of stabilization of a manufacturing process, base 10 is preferably partially removed such that base 10 by a thickness not smaller than 100 μm in a perpendicular direction from the interface with SiC crystal 11 remains. It is noted that the present step is not essential and the step (step S3) which will be described later may be performed without performing the present step.

(Step of Removing Base From SiC Crystal)

Referring next to FIGS. 1 and 5, base 10 is removed from SiC crystal 11 by oxidizing carbon forming base 10 (step S3). In the present step, base 10 can be removed as follows.

Referring to FIG. 6, initially, base 10 on which SiC crystal 11 has been formed is accommodated in an internal space 61 of a heating apparatus 60. Internal space 61 of heating apparatus 60 does not have to hermetically be sealed and it may communicate with the outside. Then, internal space 61 is heated by a heating portion 62 provided in heating apparatus 60. A construction of heating portion 62 is not particularly limited and for example, a heating wire, a ceramic heater, a quartz heating tube, or the like can be employed. It is noted that a position where heating portion 62 is arranged and the number of heating portions 62 are not limited to the form shown in FIG. 6.

Base 10 arranged in internal space 61 is thus heated. In addition, a gas containing oxygen atoms (0) is present in internal space 61 of heating apparatus 60. Therefore, in the present step, solid carbon forming base 10 is oxidized by oxygen atoms in internal space 61 and converted to a carbon oxide gas such as a carbon monoxide gas (CO) or a carbon dioxide gas (CO₂). Solid base 10 is thus removed from SiC crystal 11, and finally SiC crystal 11 of which surface 11 a having been in contact with base 10 is exposed can be obtained as shown in FIG. 5, with the entire base 10 having been removed.

In addition, in the present step, not only base 10 but also SiC crystal 11 are similarly heated. Specifically, as internal space 61 is heated, the entire SiC crystal 11 is uniformly heated. Therefore, an effect of annealing SiC crystal 11 can also be expected.

A gas containing oxygen atoms is preferably air. In this case, internal space 61 can be filled with air in a simplified manner. In addition, an atmosphere containing an oxygen gas by 1 volume % or more is preferably set in internal space 61. Thus, oxidation of base 10 can be promoted. Among others, an inert gas atmosphere containing an oxygen gas by 1 volume % or more is preferably set. Thus, oxidation of base 10 can be promoted and other unintended reactions can be suppressed, and hence carbon can further efficiently be oxidized. An argon gas, a helium gas, a nitrogen gas, or the like can be selected as an inert gas. It is noted that, from a point of view of promoted oxidation of carbon, a volume of an oxygen gas in internal space 61 is preferably high, however, a volume higher than 80 volume % may cause a problem in terms of safety due to presence of a flammable substance or the like or may lead to increase in temperature of a heated element to a set temperature or higher by abrupt combustion of carbon in the base. Therefore, a content of an oxygen gas in internal space 61 is preferably not higher than 80 volume %.

In addition, in the present step, base 10 is preferably heated to a temperature not lower than 500° C. Thus, oxidation of base 10 can be promoted and carbon can efficiently be oxidized. Therefore, consequently, a cycle time for manufacturing SiC crystal 11 can be reduced. Furthermore, base 10 is preferably heated to a temperature lower than 1800° C. Thus, such influence as etching of SiC crystal 11 can be suppressed. More preferably, a heating temperature is not lower than 800° C. and not higher than 1200° C.

Moreover, in the present step, as shown in FIG. 6, base 10 is preferably arranged in heating apparatus 60 such that base 10 and an inner wall 60a of heating apparatus 60 are not in contact with each other. Thus, since the entire exposed surface of base 10 is exposed in heating apparatus 60, efficiency of contact between base 10 and oxygen atoms or an oxygen gas in internal space 61 improves. Therefore, a time period for oxidizing base 10 can be reduced and hence a cycle time for manufacturing SiC crystal 11 can be reduced.

As described above in detail, in the present first embodiment, SiC crystal having polycrystalline structure and separated from a base can be manufactured. Though SiC crystal formed with the sublimation method is integrated with a base, the base can chemically be removed by being oxidized and gasified according to the present first embodiment. Therefore, it is not necessary to apply physical force to the SiC crystal or the base for separating them from each other. Thus, occurrence of a defect in SiC crystal attributed to application of physical force can be suppressed. Therefore, high-quality SiC crystal having fewer defects can be manufactured.

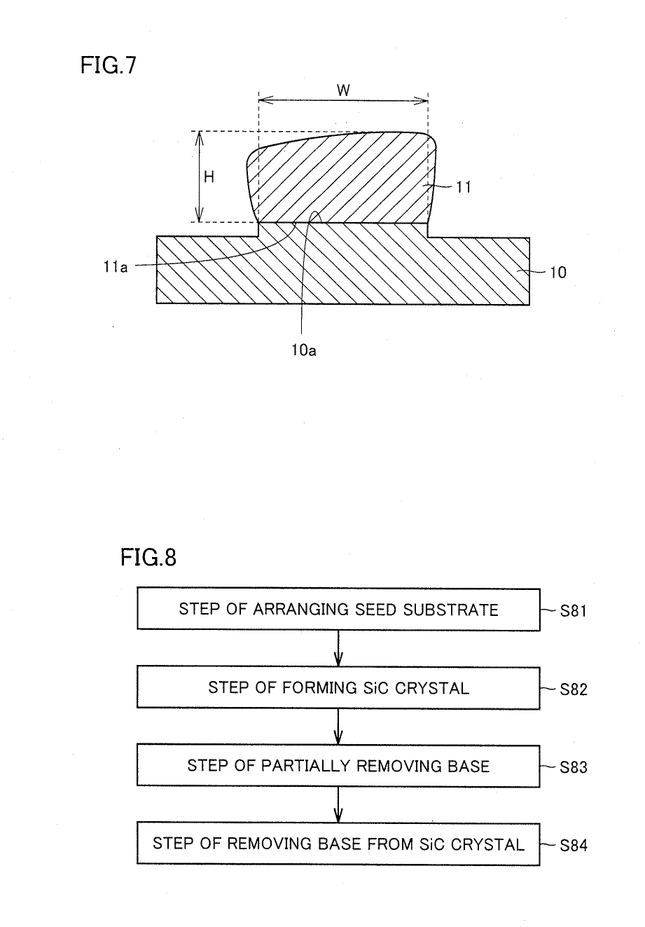

Among others, a ratio H/W between a maximum width W of a surface of the SiC crystal in contact with the base and a maximum length H in a direction of growth of the SiC crystal orthogonal to the surface in contact is preferably not higher than 2/5. Specifically, referring to FIG. 7, ratio H/W between maximum width W of surface 11a of SiC crystal 11 in contact with base 10 and maximum length H in a direction of growth (an upward direction in FIG. 7) of SiC crystal 11 orthogonal to that surface 11a is preferably not higher than 2/5. It is noted that maximum width W of surface 11a matches with a width (a lateral direction in the figure) of main surface 10a of base 10. The present inventors have found that, when SiC crystal and a base are physically separated from each other in the case where the SiC crystal has a shape satisfying the ratio above, a probability of occurrence of defects in SiC crystal 11 tends to increase. Therefore, in the SiC crystal having the shape above, an effect described above can more highly be exhibited.

In addition, SiC crystal obtained in the present first embodiment is an ingot. For example, as the ingot is sliced by a wire saw or the like, it can be used as an SiC substrate for a semiconductor device. Since this SiC crystal has been separated from the base, damage to the facilities such as cutting of the wire saw can be suppressed and hence cost for manufacturing an SiC substrate can be reduced and yield can be improved.

Moreover, according to the SiC crystal obtained in the present first embodiment, a surface having been in contact with the base (see surface 11a in FIG. 5) can be exposed. This surface is a plane formed on the main surface of the base and its accuracy as a reference plane is high.

Namely, when a surface close to a point of start of growth of SiC crystal is exposed by physically cutting the base and the SiC crystal, planarity of that surface will vary depending on accuracy in cutting. Therefore, in the case where that surface is defined as the reference plane at the time of slicing, variation in slicing process due to variation of the reference plane is caused and excessive loss may be caused in use of the ingot. In contrast, according to the SiC crystal obtained in the present first embodiment, since the surface having been in contact with the base can be defined as the reference plane, planarity of the reference plane can also readily be ensured by ensuring planarity of the main surface of the base. Therefore, highly accurate slicing is enabled and loss in use of the ingot can be suppressed.

Furthermore, according to the present first embodiment, under such a condition that oxygen atoms are present, not only the base but also the SiC crystal are heated. Therefore, an oxide film is formed on a surface of obtained SiC crystal. As a result of various studies conducted by the present inventors, it was found that an oxide film having a thickness around 10 Å tends to relatively uniformly be formed on a surface. As such a uniform oxide film is formed on the surface, polarity of a growth surface can be predicted in a simplified manner. Thus, it is expected that determination of pass/fail in terms of production control, such as whether or not a growth surface has become a desired growth surface, is facilitated.

It is noted that Si crystal is much lower in melting point than SiC crystal. Therefore, under a temperature condition for oxidizing carbon, chemical change in Si crystal is highly likely. Thus, it seems to be difficult to make use of the present invention in manufacturing Si crystal.

### Second Embodiment

A method of manufacturing SiC crystal having single crystal structure with a sublimation method will be described hereinafter by way of example of the present invention.

(Step of Arranging Seed Substrate)

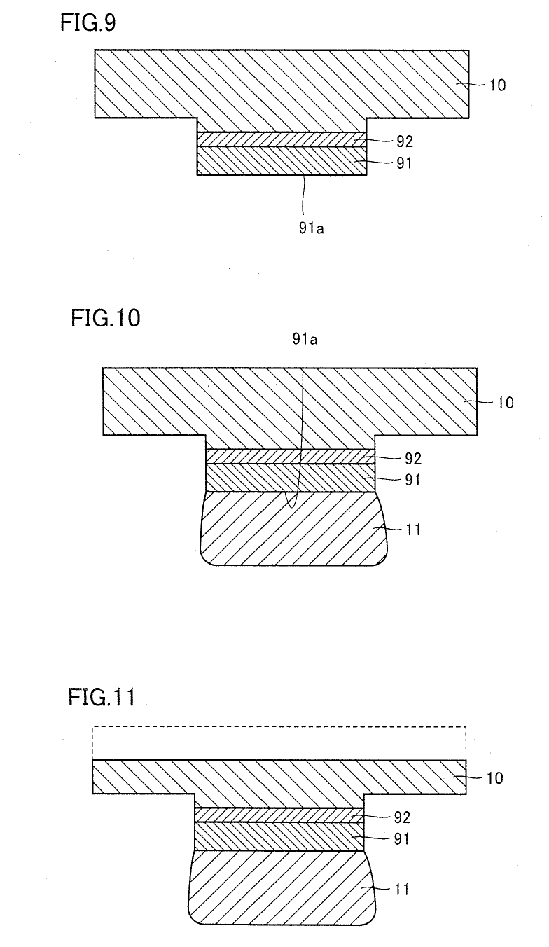

Referring to FIGS. 8 and 9, initially, a seed substrate 91 is arranged on main surface 10a (a lower surface in FIG. 9) of base 10 (step S81). In the present second embodiment, seed substrate 91 can be bonded to a side of main surface 10a of base 10 with a fixing portion 92, as shown in FIG. 9.

Seed substrate 91 is made of SiC crystal having single crystal structure (hereinafter referred to as “SiC single crystal”), and crystal structure thereof is preferably hexagonal and more preferably 4H-SiC or 6H-SiC among others. Seed substrate 91 has a surface 91a (a lower surface in the figure) which is a surface on which SiC crystal 11 is to grow and a back surface (an upper surface in the figure) which is a surface to be attached to base 10. A thickness of seed substrate 91 (a dimension in a vertical direction in the figure) is, for example, not smaller than 0.5 mm and not greater than 10 mm. In addition, a two-dimensional shape of seed substrate 91 preferably encompasses a circle having a diameter of 100 mm.

In addition, an off angle (inclination) of a plane orientation of surface 91 a of seed substrate 91 from a {0001} plane, that is, an off angle from a (0001) plane or a (000-1) plane, is preferably not greater than 15° and more preferably not greater than 5°. Thus, occurrence of a defect during epitaxial growth of silicon carbide can be suppressed. Alternatively, an off angle of surface 91a from the {0001} plane may be not smaller than 80°. Thus, for example, SiC crystal 11 suitable for obtaining an SiC substrate by cutting, which has a plane high in channel mobility such as a {11-20} plane or a {1-100} plane, can be grown. Alternatively, an off angle of surface 91a from the {0001} plane may be not smaller than 50° and not greater than 60°. Thus, for example, SiC crystal 11 suitable for obtaining an SiC substrate by cutting, which has a plane high in channel mobility such as a {03-38} plane, can be grown.

Fixing portion 92 is composed of carbon (C). Fixing portion 92 can be formed, for example, by applying an adhesive cured by being heated and composed of carbon to main surface 10a of base 10 or to a back surface of seed substrate 91, compression bonding main surface 10a of base 10 and the back surface of seed substrate 91 to each other, and thereafter heating and curing the adhesive. A heating temperature for curing the adhesive is preferably not lower than 1000° C. and more preferably not lower than 2000° C. In addition, this heating is preferably carried out in an inert gas.

Fixing portion 92 is preferably formed as an adhesive containing a resin converted to non-graphitizable carbon as a result of heating, diamond fine particles, and a solvent, among others. Non-graphitizable carbon refers to carbon having such an irregular structure that development of a graphite structure is suppressed when it is heated in an inert gas. Examples of resins converted to non-graphitizable carbon as a result of heating include a novolac resin, a phenol resin, or a furfuryl alcohol resin.

An amount of diamond fine particles is preferably smaller than an amount of a resin, with the number of moles of carbon atoms being defined as the reference. A diamond fine particle has a particle size, for example, from 0.1 to 10 Å solvent capable of dissolving and dispersing the resin above and carbohydrate therein is selected as the solvent as appropriate. In addition, this solvent is not limited to a solvent composed of a liquid of a single type and it may be a liquid mixture of a plurality of types of liquids. For example, a solvent containing alcohol dissolving carbohydrate and cellosolve acetate dissolving a resin may be employed.

In the case where fixing portion 92 is formed with the adhesive above, volume increase due to change from diamond fine particles to graphite fine particles at the time of curing of the adhesive can compensate for volume decrease due to change from the resin to non-graphitizable carbon. Therefore, in fixing portion 92 formed by curing of the adhesive, generation of pores due to this volume decrease can be suppressed. Thus, since lowering in thermal conductivity of fixing portion 92 due to presence of pores can be suppressed, a temperature of seed substrate 91 fixed by fixing portion 92 can be more uniform. Therefore, in the step of forming SiC crystal which will be described later, high-quality SiC crystal can be grown on seed substrate 91.

In addition, when the adhesive is converted to fixing portion 92, diamond fine particles or graphite fine particles resulting from conversion of these diamond fine particles are present. These fine particles have a function to uniformly distribute non-graphitizable carbon formed as a result of heating of the resin in the adhesive at a high temperature, and thus a filling factor of fixing portion 92 can be enhanced. Thus, thermal conductivity of fixing portion 92 can be enhanced.

Moreover, the adhesive may originally contain graphite fine particles in addition to diamond fine particles. Thus, a ratio between an amount of diamond fine particles of which volume increases as they are converted to graphite during curing and an amount of graphite fine particles of which volume remains unchanged because they are originally graphite can be adjusted. Through such adjustment, a degree of volume increase in fine particles while the adhesive is cured can be adjusted, and hence fixing portion 92 having a desired thickness can readily be formed.

Preferably, the adhesive contains carbohydrate. Sugars or a derivative thereof can be employed as carbohydrate. The sugars may be monosaccharide such as glucose or polysaccharide such as cellulose. In addition, a component of the adhesive may contain a component other than the component described above. For example, such an additive as a surfactant and a stabilizer may be contained.

(Step of Forming SiC Crystal)

Referring next to FIGS. 8 and 10, SiC crystal 11 is formed on surface 91 a of seed substrate 91 (step S82). In the present step, since SiC crystal is formed with the sublimation method the same as the sublimation method described in detail in connection with step Si in the first embodiment, description thereof will not be repeated.

In the present second embodiment, SiC crystal 11 having single crystal structure can readily be formed on surface 91a of seed substrate 91. Preferably, a two-dimensional shape of surface 91a of seed substrate 91 encompasses a circle having a diameter of 100 mm. Thus, a substrate composed of SiC single crystal and having a two-dimensional shape encompassing a circle having a diameter of 100 mm can readily be obtained from SiC crystal 11 grown on this seed substrate 91.

Though a substrate formed of SiC has been exemplified as seed substrate 91 in the present second embodiment, a substrate formed of other materials may be employed, and for example, GaN, ZnSe, ZnS, CdS, CdTe, MN, or BN can be employed as such a material.

(Step of Partially Removing Base)

Referring next to FIGS. 8 and 11, base 10 is partially removed (step S83). Since the present step is the same as step S2 in the first embodiment, description thereof will not be repeated.

(Step of Removing Base From SiC Crystal)

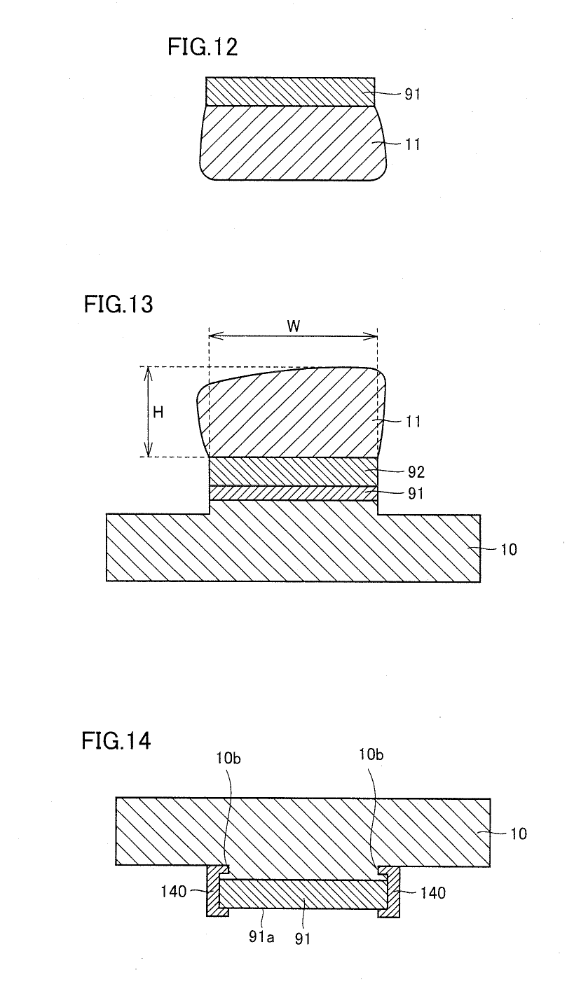

Referring next to FIGS. 8 and 12, base 10 is removed from SiC crystal 11 by oxidizing carbon forming base 10 (step S84). Since the present step is the same as step S3 in the first embodiment, description thereof will not be repeated.

Since fixing portion 92 is composed of carbon here, in the present step, fixing portion 92 is removed from the surface of seed substrate 91 as it is oxidized and gasified similarly to base 10. Therefore, after the present step, as shown in FIG. 12, only SiC crystal 11 and seed substrate 91 remain.

As described above in detail, in the present second embodiment, SiC crystal having single crystal structure can be manufactured. Though the base is integrated with SiC single crystal formed with the sublimation method, the base can chemically be removed by oxidizing and gasifying the base according to the present second embodiment. Therefore, it is not necessary to apply physical force to the SiC single crystal or the base for separating them from each other. Therefore, occurrence of a defect in SiC single crystal attributed to application of physical force can be suppressed. Therefore, high-quality SiC single crystal having fewer defects can be manufactured.

Among others, ratio H/W between maximum width W of a surface of the SiC crystal in contact with the base and maximum length H in a direction of growth of SiC single crystal orthogonal to the surface in contact is preferably not higher than 2/5, which is the same as in the first embodiment. Specifically, referring to FIG. 13, ratio H/W between maximum width W of surface 11a of SiC crystal 11 in contact with base 10 and maximum length H in a direction of growth (an upward direction in FIG. 13) of SiC crystal 11 orthogonal to that surface 11a is preferably not higher than 2/5.

In addition, though fixing portion 92 obtained by curing the adhesive has been exemplified in the present second embodiment, fixing portion 92 may have other constructions. For example, referring to FIG. 14, a fixing portion 140 may be a jig for fixing seed substrate 91 and base 10 to each other by sandwiching a groove portion 10b provided in base 10 and surface 91a of seed substrate 91. In this case as well, in step S84 described above, fixing portion 92 composed of carbon can be removed similarly to base 10. Furthermore, in this case, base 10 and seed substrate 91 can be fixed in a simplified manner.

Though a method of manufacturing SiC crystal with the sublimation method has been described in the first and second embodiments above, a method of growing SiC crystal on the base is not limited to the sublimation method. For example, SiC crystal may be manufactured on the base with such a vapor phase epitaxy method as a high-speed CVD method or such a liquid phase epitaxy method as a melt growth method, and thereafter the base may be removed by oxidation.

### EXAMPLES

The present invention will further specifically be described with reference to Example and Comparative Examples. It is noted that the present invention is not limited by these Example and Comparative Examples.

### Example 1

Initially, a crucible made of graphite was filled with high-purity SiC powders such that a surface became flat. In addition, a seed substrate was fixed to a main surface of a base made of graphite, with a fixing portion being interposed by curing a novolac resin. As the seed substrate, 4H-SiC single crystals of various sizes having a circular main surface shape, a diameter from 25 to 100 mm (1 to 4 inches), and a thickness from 0.4 to 2 mm were employed. It is noted that an off angle from the (0001) plane was 8°, with regard to a plane orientation of a main surface opposite to the surface of the seed substrate opposed to the base.

Then, an He gas or an Ar gas was introduced in the crucible and a pressure of an atmosphere in the crucible was reduced to 300 to 700 Torr. At the same time, a high-frequency heating coil was used to heat the atmosphere in the crucible such that a temperature of the atmosphere in the crucible attained to 2000 to 2300° C. Then, the pressure was reduced to 100 Torr or lower, SiC crystal having a longest length in a direction of growth of crystal of 2 cm or longer was grown, and thereafter the temperature in the crucible was cooled to a room temperature.

Then, a structure constituted of the base, the fixing portion, the seed substrate, and the SiC crystal was accommodated in a heat treatment apparatus and a temperature in the heat treatment apparatus was raised from the room temperature to 1000° C. at a rate of 1000° C./hour. It is noted that an atmosphere in the heat treatment apparatus was set to such a condition that air could flow therein. Then, the temperature in the heat treatment apparatus was maintained at 1000° C. and a state of the accommodated structure above was visually observed. Then, it was confirmed that the base and the fixing portion were completely removed after 48 hours. Then, this SiC crystal was sliced with a wire saw and 300 SiC substrates each having a thickness of 450 mm were fabricated. Then, a break of the wire was not observed and quality of each fabricated SiC substrate was also good.

### Comparative Example 1

SiC crystal having a longest length in a direction of growth of crystal of 2 cm or longer was grown, with the method the same as in Example 1. Then, a structure constituted of the base, the fixing portion, the seed substrate, and the SiC crystal was sliced with the wire saw above to thereby fabricate 300 SiC substrates each having a thickness of 450 mm. Then, the wire was broken and crack was caused in 20 SiC substrates by this break.

### Comparative Example 2

SiC crystal having a longest length in a direction of growth of crystal of 2 cm or longer was grown, with the method the same as in Example 1. Then, mechanical peeling for separation between the fixing portion and the seed substrate was attempted in a structure constituted of the base, the fixing portion, the seed substrate, and the SiC crystal. On the surface of the SiC seed substrate that was peeled off, however, peeling like craters was observed. Therefore, it was found that a surface portion of the SiC seed substrate exposed as a result of peeling could not be made use of as the SiC substrate.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method of manufacturing silicon carbide crystal, comprising the steps of:
forming silicon carbide crystal on a main surface of a base composed of carbon; and
removing said base from said silicon carbide crystal by oxidizing said carbon.

2. The method of manufacturing silicon carbide crystal according to claim 1, comprising the step of arranging a seed substrate composed of silicon carbide single crystal on the main surface of said base before said step of forming silicon carbide crystal.

3. The method of manufacturing silicon carbide crystal according to claim 2, wherein
in said step of arranging a seed crystal, said seed substrate is fixed to the main surface of said base by using a fixing portion composed of carbon.

4. The method of manufacturing silicon carbide crystal according to claim 1, wherein
in said step of removing said base, said base is heated to a temperature not lower than 500° C. and lower than 1800° C.

5. The method of manufacturing silicon carbide crystal according to claim 1, wherein
in said step of removing said base, said base is arranged in an atmosphere containing oxygen by not less than 1 volume %.

6. The method of manufacturing silicon carbide crystal according to claim 1, further comprising the step of partially removing said base between said step of foaming silicon carbide crystal and said step of removing said base.

7. The method of manufacturing silicon carbide crystal according to claim 1, wherein
said step of removing said base has the steps of accommodating said base in an internal space of a heating apparatus and heating accommodated said base by heating the internal space of said heating apparatus, and
in said step of accommodating said base, said base is arranged in said heating apparatus such that said base and an inner wall of said heating apparatus are not in contact with each other.

8. The method of manufacturing silicon carbide crystal according to claim 1, wherein
a ratio H/W between a maximum width W of a surface of said silicon carbide crystal in contact with said base and a maximum length H in a direction of growth of said silicon carbide crystal orthogonal to said surface in contact is not higher than 2/5.
